(19) United States
(12) Patent Application Publication
(10) Pub. No.: US 2022/0336317 A1
(43) Pub. Date: Oct. 20, 2022

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventor: Chang-Lin YEH, Kaohsiung (TW)

(73) Assignee: Advanced Semiconductor Engineering, Inc., Kaohsiung (TW)

(21) Appl. No.: 17/233,287

(22) Filed: Apr. 16, 2021

(51) Int. Cl. H01L 23/367; H01L 23/42; H01L 21/56

(52) U.S. Cl. CPC H01L 23/3672; H01L 23/42; H01L 21/56

(57) ABSTRACT

A semiconductor device package and a method for manufacturing the semiconductor device package are provided. The semiconductor device package includes a first substrate with a aperture, a second substrate disposed on the first substrate, a first electronic component disposed on the second substrate, an encapsulant disposed on the first substrate and covering the second substrate and a first heat dissipation structure extending through the aperture and attached to the second substrate.

### BACKGROUND

### 1. Field of the Disclosure

The instant disclosure relates to, amongst other things, a semiconductor device package and method of manufacturing the same, and a semiconductor device package having two heat dissipation structures which are respectively disposed on the upper side and the lower side of the semiconductor device package.

### 2. Description of Related Art

In 2.5 D/3 D semiconductor packages, an interposer (e.g., a through silicon via (TSV) interposer) provides electrical interconnection in the vertical direction. However, since the function and performance of the chip are improved, the power consumption of the chip would be increased accordingly. As the power consumption of the chip increases, heat dissipation can become desirable in some implementations. Thus, it can be useful in some implementations to provide a 2.5 D/3 D semiconductor package with improved heat dissipation.

### SUMMARY

According to one example embodiment of the instant disclosure, a semiconductor device package includes a first substrate with a aperture, a second substrate disposed on the first substrate, a first electronic component disposed on the second substrate, an encapsulant disposed on the first substrate and covering the second substrate, a first heat dissipation structure extending through the aperture and attached to the second substrate.

According to another example embodiment of the instant disclosure, a semiconductor device package includes a carrier, a package structure staked on the carrier, a first heat dissipation structure extending through the carrier and into the package structure and a first thermal interface material (between the first heat dissipation structure and the set of components.

According to another example embodiment of the instant disclosure, method of manufacturing a semiconductor device package includes providing a semiconductor structure with a set of stacked components; providing an intermediate structure on a portion of the semiconductor structure; forming an encapsulant on the semiconductor structure to cover the set of stacked components and the temporary structure wherein the portion of the semiconductor structure which is provided with the intermediate structure is free of being encapsulated by the encapsulant; and providing a heat dissipation structure on the semiconductor structure or the intermediate structure.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

FIG. 1A is a cross-sectional view of a semiconductor device package in accordance with an embodiment of the instant disclosure.

FIG. 1B is an enlarged view of portion “A” illustrated in FIG. 1A.

FIG. 2A is a cross-sectional view of a semiconductor device package in accordance with an embodiment of the instant disclosure.

FIG. 2B is an enlarged view of portion “B” illustrated in FIG. 2A.

FIG. 3 is a cross-sectional view of a semiconductor device package in accordance with an embodiment of the instant disclosure.

FIG. 4A is a cross-sectional view of a semiconductor device package in accordance with an embodiment of the instant disclosure.

FIG. 4B is an enlarged view of portion “C” illustrated in FIG. 4A.

FIG. 4C is another enlarged view of portion “C” illustrated in FIG. 4A.

FIG. 5 is a cross-sectional view of a semiconductor device package in accordance with an embodiment of the instant disclosure.

FIG. 6A, FIG. 6B, FIG. 6C, FIG. 6D and FIG. 6E illustrate a method of manufacturing a semiconductor device package in accordance with another embodiment of the instant disclosure.

FIG. 7A, FIG. 7B, FIG. 7C and FIG. 7D illustrate a method of manufacturing a semiconductor device package in accordance with another embodiment of the instant disclosure.

FIGS. 8A, 8B. 8C, 8D, 8E and 8F illustrate a method of manufacturing a semiconductor device package in accordance with another embodiment of the instant disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the FIGures. The spatially relative terms are intended to encompass different orientations of the device in use or operation in addition to the orientation depicted in the FIGures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Present disclosure provides a semiconductor device package including a 2.5 D or 3 D semiconductor package. The semiconductor device package has a heat dissipation structure extending through the substrate and the motherboard/PCB of the semiconductor device package respectively.

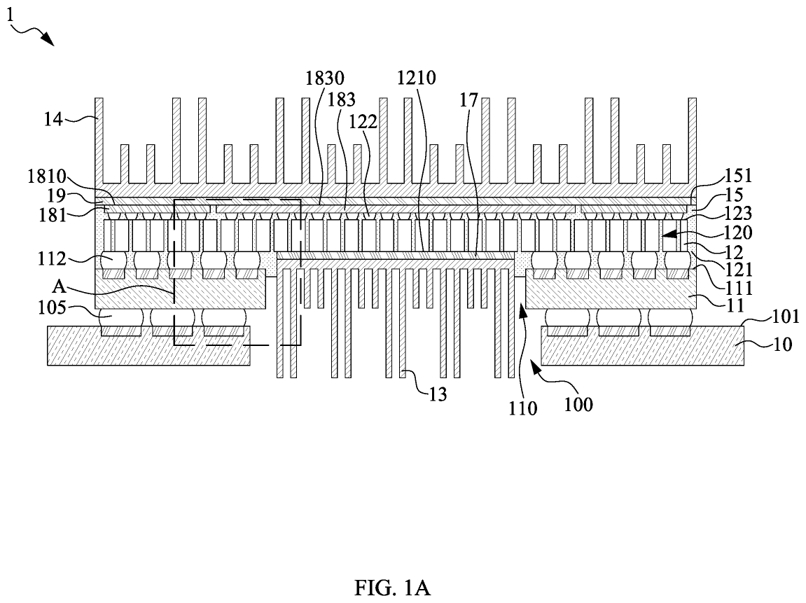

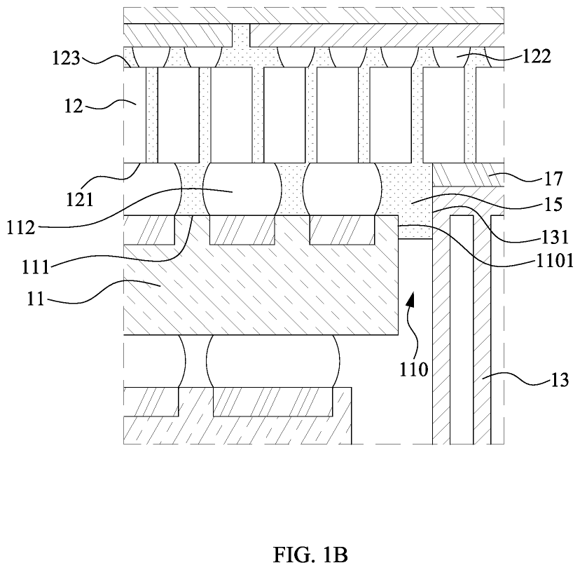

FIG. 1A is a cross-sectional view of a semiconductor device package 1 in accordance with some embodiments of the present disclosure. As shown in FIG. 1A, the semiconductor device package 1 includes a motherboard 10, a substrate 11, an interposer 12, heat sinks 13 and 14 and an encapsulant 15. In some embodiments of the present disclosure, the motherboard 10 includes a printed circuit board.

The motherboard 10 may have a surface 101 (e.g., an upper surface) and the substrate 11 may be disposed or mounted on the surface 101 of the motherboard 10. In some embodiments of the present disclosure, electrical connections 105 are disposed between the motherboard 10 and the substrate 11 so as to electrically connect the substrate 11 to the motherboard 10. The electrical connection 105 may include a solder ball or a solder bump such as a C4 bump. Further, the substrate 11 may have a surface 111 (e.g., an upper surface) facing away from the motherboard 10, and the interposer 12 may be disposed or mounted on the surface 111 of the substrate 11 so that the interposer 12 may be stacked on the substrate 11. In some embodiments of the present disclosure, the interposer 12 includes conductive vias 120 such as through silicon vias (TSVs). The interposer 12 may have a surface 121 (e.g., a lower surface) facing the surface 111 of the substrate 11. In some embodiments of the present disclosure, electrical connections 112 are disposed between the surface 121 of the interposer 12 and the surface 111 of the substrate 11 so as to electrically connect the interposer 12 to the substrate 11. The electrical connection 112 may include a C4 bump, a micro bump, a solder ball or a copper pillar.

The interposer 12 may have a surface 123 (e.g., an upper surface) facing away from the surface 111 of the substrate 11, and electronic components 181, 183 may be disposed or mounted on the surface 123 of the interposer 12. The electronic components 181, 183 may be a die, an active device, a passive device, and/or other electronic devices. In some embodiments of the present disclosure, electrical connections 122 are disposed between the surface 123 of the interposer 12 and the electronic components 181, 183 so as to electrically connect the electronic components 181, 183 to the interposer 12. The electrical connection 122 may include a C4 bump, a micro bump, a solder ball or a copper pillar.

As shown in FIG. 1A, the encapsulant 15 (i.e., package body) may be disposed on the surface 111 of the substrate 11 and configured to cover, encapsulate or surround the surface 111 of substrate 11, the interposer 12 and the electronic components 181 and 183. The encapsulant 15 may include molding compounds, such as a Novolac-based resin, an epoxy-based resin, a silicone-based resin, or other another suitable encapsulant; fillers such as silicon oxide fillers, may be included in the molding compound. In addition, the encapsulant 15 may include a molding underfill (MUF) or a capillary underfill (CUF). In some embodiments of the present disclosure, the encapsulant 15 covers the surfaces 121 and 123 of the interposer 12. In some embodiments of the present disclosure, the encapsulant 15 surrounds the interposer 12. In some embodiments of the present disclosure, the encapsulant 15 covers the side surfaces of the interposer 12. In some embodiments of the present disclosure, the encapuslant 15 does not cover the side surface of the interposer 12. In some embodiments of the present disclosure, the encapsulant 15 surrounds the electrical connections 112 arranged between the interposer 12 and the substrate 11. In some embodiments of the present disclosure, the encapsulant 15 surrounds the electrical connections 122 arranged between the interposer 12 and the electronic components 181, 183. Further, the encapsulant 15 may have a surface 151 (e.g., an upper surface) facing away from the substrate 11, and the electronic component 181, 183 may have a surface 1810, 1830 (e.g., an upper surface) which may be exposed from the surface 151 of the encapsulant 15 and substantially coplanar with the surface 151 of the encapsulant 15.

Referring to FIG. 1A, the motherboard 10 may include an aperture 100 extending through the motherboard 10, and the substrate 11 may include an aperture 110 extending through the substrate 11. The aperture 110 of the substrate 11 may substantially align with the aperture 100 of the motherboard 10. Further, the surface 121 of the interposer 12 may include a portion 1210 which may be exposed from the encapsulant 15 and substantially align with the aperture 110 of the substrate 11 and the aperture 100 of the motherboard 10. As shown in FIG. 1A, the heat sink 13 is attached to the portion 1210 of the surface 121 of the interposer 12. In some embodiments of the present disclosure, the heat sink 13 extends through the aperture 110 of the substrate 11 and the aperture 100 of the motherboard 10 and extends to the outside of the semiconductor device package 1 so that the heat sink 13 is configured to transfer the heat, which may be generated by the electronic component(s) 181, 183 in the semiconductor device package 1, from the interior of the semiconductor device package 1 to the outside of the semiconductor device package 1. A thermal interface material 17 (TIM) is arranged between the surface 121 of the interposer 12 and the heat sink 13. That is, the interposer 12 is thermally connected to the heat sink 13 through the thermal interface material 17.

Moreover, the heat sink 14 may be disposed on or attached to the surface 151 of the encapsulant 15, the surface 1810 of the electronic component 181 and the surface 1830 of the electronic component 183 so that the heat sink 14 is configured to dissipate the heat generated from the electronic components 181, 183. A thermal interface material 19 (TIM) is arranged between the heat sink 14 and the surface 151 of the encapsulant 15, between the heat sink 14 and the surface 1810 of the electronic component 181 and between the heat sink 14 and the surface 1830 of the electronic component 183. That is, the encapsulant 15 and the electronic components 181, 183 are thermally connected to the heat sink 14 through the thermal interface material 19.

FIG. 1B is an enlarged view of portion “A” illustrated in FIG. 1A. As shown in FIG. 1B, the encapsulant 15 may cover the surfaces 121 and 123 of the interposer 12 and the surface 111 of the substrate 11 and surrounds the electrical connections 112 and 122. Referring to FIG. 1B, the heat sink 13 is located within the aperture 110 of the substrate 11 and has a side surface 131 facing and spaced from the inner surface 1101 of the aperture 110 of the substrate 11. In some embodiments of the present disclosure, the encapsulant 15 covers or contacts the inner surface 1101 of the aperture 110 of the substrate 11 and the side surface 131 of the heat sink 13. In other words, there is a gap between the substrate 11 and the heat sink 13 and the encapsulant 15 may extend into the gap between the substrate 11 and the heat sink 13. The encapsulant 15 is configured to extend into the gap between the substrate 11 and the heat sink 131 and cover or contact the inner surface 1101 of the aperture 110 of the substrate 11 and the side surface 131 of the heat sink 13, and thus functions as a mold lock. Further, the encapsulant 15 may cover or contact the thermal interface material 17.

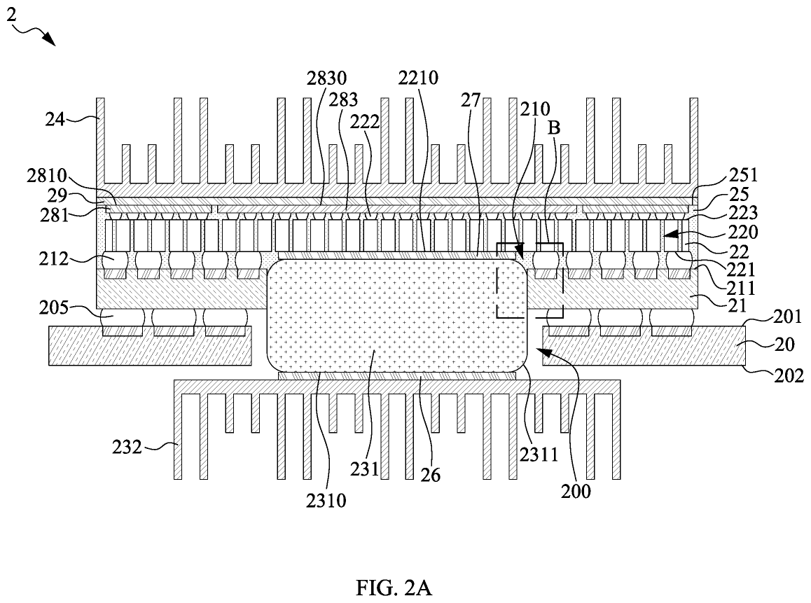

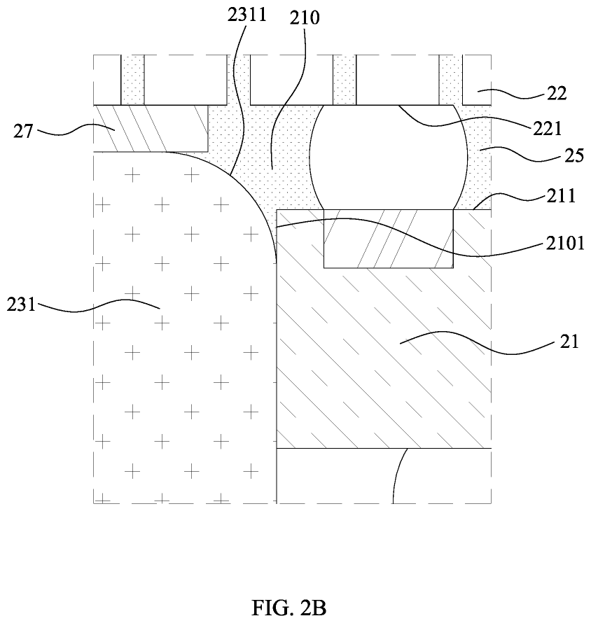

FIG. 2A is a cross-sectional view of a semiconductor device package 2 in accordance with some embodiments of the present disclosure. As shown in FIG. 2A, the semiconductor device package 2 includes a motherboard 20, a substrate 21, an interposer 22, heat sinks 232 and 24, thermal spacer 231 and an encapsulant 25. In some embodiments of the present disclosure, the motherboard 20 includes a printed circuit board.

The motherboard 20 may have a surface 201 (e.g., an upper surface) and a surface 202 (e.g., a lower surface) opposite to the surface 201 and the substrate 21 may be disposed or mounted on the surface 201e of the motherboard 20. In some embodiments of the present disclosure, electrical connections 205 are disposed between the motherboard 20 and the substrate 21 so as to electrically connect the substrate 21 to the motherboard 20. The electrical connection 205 may include a solder ball or a solder bump such as a C4 bump. Further, the substrate 21 may have a surface 211 (e.g., an upper surface) facing away from the motherboard 20, and the interposer 22 may be disposed or mounted on the surface 211 of the substrate 21 so that the interposer 22 may be stacked on the substrate 21. In some embodiments of the present disclosure, the interposer 22 includes conductive vias 220 such as through silicon vias (TSVs). The interposer 22 may have a surface 221 (e.g., a lower surface) facing the surface 211 of the substrate 21. In some embodiments of the present disclosure, electrical connections 212 are disposed between the surface 221 of the interposer 22 and the surface 211 of the substrate 21 so as to electrically connect the interposer 22 to the substrate 21. The electrical connection 211 may include a C4 bump, a micro bump, a solder ball or a copper pillar.

The interposer 22 may have a surface 223 (e.g., an upper surface) facing away from the surface 211 of the substrate 21, and electronic components 281, 283 may be disposed or mounted on the surface 223 of the interposer 22. The electronic component 281, 283 may be a die, an active device, a passive device, and/or other electronic devices. In some embodiments of the present disclosure, electrical connections 222 are disposed between the surface 223 of the interposer 22 and the electronic components 281, 283 so as to electrically connect the electronic components 281, 283 to the interposer 22. The electrical connection 222 may include a C4 bump, a micro bump, a solder ball or a copper pillar.

As shown in FIG. 2A, the encapsulant 25 (i.e., package body) may be disposed on the surface 211 of the substrate 21 and configured to cover, encapsulate or surround the surface 211 of substrate 21, the interposer 22 and the electronic components 281 and 283. The encapsulant 25 may include molding compounds, such as a Novolac-based resin, an epoxy-based resin, a silicone-based resin, or other another suitable encapsulant; fillers such as silicon oxide fillers, may be included in the molding compound. In addition, the encapsulant 25 may include a molding underfill (MUF) or a capillary underfill (CUF). In some embodiments of the present disclosure, the encapsulant 25 covers the surfaces 221 and 223 of the interposer 22. In some embodiments of the present disclosure, the encapsulant 25 surrounds the interposer 22. In some embodiments of the present disclosure, the encapsulant 25 covers the side surfaces of the interposer 22. In some embodiments of the present disclosure, the encapsulant 25 does not cover the side surface of the interposer 22. In some embodiments of the present disclosure, the encapsulant 25 surrounds the electrical connections 212 arranged between the interposer 22 and the substrate 21. In some embodiments of the present disclosure, the encapsulant 25 surrounds the electrical connections 222 arranged between the interposer 22 and the electronic components 281, 283. Further, the encapsulant 25 may have a surface 251 (e.g., an upper surface) facing away from the substrate 21, and the electronic component 281, 283 may have a surface 2810, 2830 (e.g., an upper surface) which may be exposed from the surface 251 of the encapsulant 25 and substantially coplanar with the surface 251 of the encapsulant 25.

Referring to FIG. 2A, the motherboard 20 may include an aperture 200 extending through the motherboard 20, and the substrate 21 may include an aperture 210 extending through the substrate 21. The aperture 210 of the substrate 21 may substantially align with the aperture 200 of the motherboard 20. Further, the surface 221 of the interposer 22 may include a portion 2210 which may be exposed from the encapsulant 25 and substantially align with the aperture 210 of the substrate 21 and the aperture 200 of the motherboard 20. As shown in FIG. 2A, the thermal spacer 231 is attached to the portion 2210 of the surface 221 of the interposer 21. In some embodiments of the present disclosure, the thermal spacer 231 extends through the aperture 210 of the substrate 21 and the aperture 200 of the motherboard 20 and extends to the outside of the semiconductor device package 2. In some embodiments of the present disclosure, the thermal spacer 23 includes a surface 2310 facing away from the interposer 22 and protruding from an elevation of the surface 202 of the motherboard 20. A thermal interface material 27 (TIM) is arranged between the surface 221 of the interposer 22 and the thermal spacer 231. That is, the interposer 22 is thermally connected to the thermal spacer 231 through the thermal interface material 27. Further, the heat sink 232 is attached to the surface 2310 of the thermal spacer 231. In some embodiments of the present disclosure, the heat sink 232 is located outside the semiconductor device package 2 so that the heat sink 232 is configured to transfer the heat, which may be generated by the electronic component(s) in the semiconductor device package 2, from the interior of the semiconductor device package 2 to the outside of the semiconductor device package 2 through the thermal spacer 231. In some embodiments of the present disclosure, a cross-sectional width of the heat sink 232 is greater than a cross-sectional width of the aperture 200 of the motherboard 20 and/or greater than a cross-sectional width of the aperture 210 of the substrate 21 so that the efficiency of heat dissipation could be increased. A thermal interface material 26 (TIM) is arranged between the surface 2310 of the thermal spacer 231 and the heat sink 232. That is, the thermal spacer 231 is thermally connected to the heat sink 232 through the thermal interface material 26.

Moreover, the heat sink 24 may be disposed on or attached to the surface 251 of the encapsulant 25, the surface 2810 of the electronic component 281 and the surface 2830 of the electronic component 283 so that the heat sink 24 is configured to dissipate the heat generated from the electronic components 281, 283. A thermal interface material 29 (TIM) is arranged between the heat sink 24 and the surface 251 of the encapsulant 25, between the heat sink 24 and the surface 2810 of the electronic component 281 and between the heat sink 24 and the surface 2830 of the electronic component 283. That is, the encapsulant 25 and the electronic components 281, 283 are thermally connected to the heat sink 24 through the thermal interface material 29.

FIG. 2B is an enlarged view of portion “B” illustrated in FIG. 2A. As shown in FIG. 2B, the encapsulant 25 may cover the surfaces 221 of the interposer 22 and the surface 211 of the substrate 21 and surrounds the electrical connections 212. Referring to FIG. 2B, the thermal spacer 231 is located within the aperture 210 of the substrate 21 and has a side surface 2311 facing and spaced from the inner surface 2101 of the aperture 210 of the substrate 21. In some embodiments of the present disclosure, the encapsulant 25 covers or contacts the inner surface 2101 of the aperture 210 of the substrate 21 and the side surface 2311 of the thermal spacer 231. In other words, there is a gap between the substrate 21 and the thermal spacer 231 and the encapsulant 25 may extend into the gap between the substrate 21 and the thermal spacer 231. The encapsulant 25 is configured to extend into the gap between the substrate 21 and the thermal spacer 231 and cover or contact the inner surface 2101 of the aperture 210 of the substrate 21 and the side surface 2311 of the thermal spacer 231, and thus functions as a mold lock. Further, the encapsulant 25 may cover or contact the thermal interface material 27.

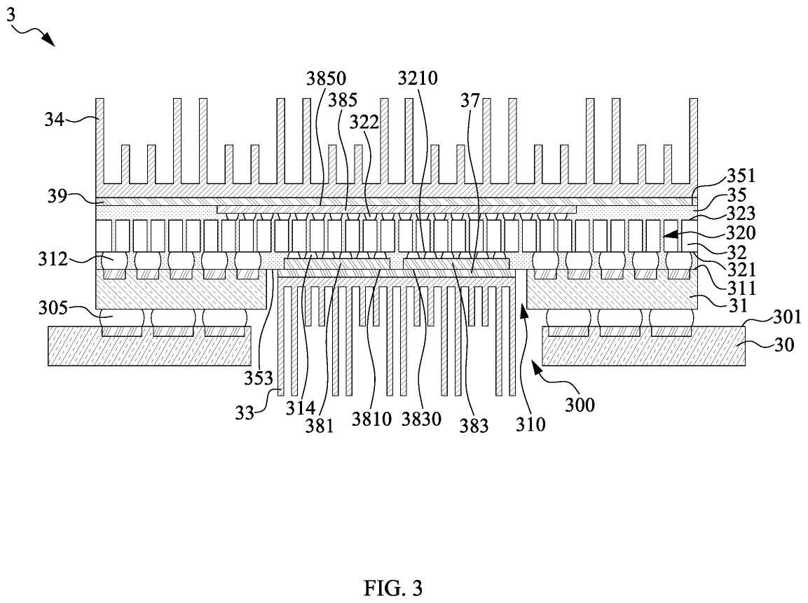

FIG. 3 is a cross-sectional view of a semiconductor device package 3 in accordance with some embodiments of the present disclosure. As shown in FIG. 3, the semiconductor device package 3 includes a motherboard 30, a substrate 31, an interposer 32, heat sinks 33 and 34 and an encapsulant 35. In some embodiments of the present disclosure, the motherboard 30 includes a printed circuit board.

The motherboard 30 may have a surface 301 (e.g., an upper surface) and the substrate 31 may be disposed or mounted on the surface 301 of the motherboard 30. In some embodiments of the present disclosure, electrical connections 305 are disposed between the motherboard 30 and the substrate 31 so as to electrically connect the substrate 31 to the motherboard 30. The electrical connection 305 may include a solder ball or a solder bump such as a C4 bump. Further, the substrate 31 may have a surface 311 (e.g., an upper surface) facing away from the motherboard 30, and the interposer 32 may be disposed or mounted on the surface 311 of the substrate 31 so that the interposer 32 may be stacked on the substrate 31. In some embodiments of the present disclosure, the interposer 32 includes conductive vias 320 such as through silicon vias (TSVs). The interposer 32 may have a surface 321 (e.g., a lower surface) facing the surface 311 of the substrate 31. In some embodiments of the present disclosure, electrical connections 312 are disposed between the surface 321 of the interposer 32 and the surface 311 of the substrate 31 so as to electrically connect the interposer 32 to the substrate 31. The electrical connection 312 may include a C4 bump, a micro bump, a solder ball or a copper pillar. Further, electronic components 381 and 383 are disposed and mounted on the surface 321 of the interposer 32. The electronic components 381, 383 may be a die, an active device, a passive device, and/or other electronic devices. In some embodiments of the present disclosure, electrical connections 314 are disposed between the surface 321 of the interposer 32 and the electronic components 381, 383 so as to electrically connect the electronic components 381, 383 to the interposer 32. The electrical connection 314 may include a C4 bump, a micro bump, a solder ball or a copper pillar.

The interposer 32 may have a surface 323 (e.g., an upper surface) facing away from the surface 311 of the substrate 31, and an electronic component 385 may be disposed or mounted on the surface 323 of the interposer 32. The electronic component 385 may be a die, an active device, a passive device, and/or other electronic devices. In some embodiments of the present disclosure, electrical connections 322 are disposed between the surface 323 of the interposer 32 and the electronic component 385 so as to electrically connect the electronic component 385 to the interposer 32. The electrical connection 322 may include a C4 bump, a micro bump, a solder ball or a copper pillar.

As shown in FIG. 3, the encapsulant 35 (i.e., package body) may be disposed on the surface 311 of the substrate 31 and configured to cover, encapsulate or surround the surface 311 of substrate 31, the interposer 32 and the electronic components 381, 383 and 385. The encapsulant 35 may include molding compounds, such as a Novolac-based resin, an epoxy-based resin, a silicone-based resin, or other another suitable encapsulant; fillers such as silicon oxide fillers, may be included in the molding compound. In addition, the encapsulant 35 may include a molding underfill (MUF) or a capillary underfill (CUF). In some embodiments of the present disclosure, the encapsulant 35 covers the surfaces 321 and 323 of the interposer 32. In some embodiments of the present disclosure, the encapsulant 35 surrounds the interposer 32. In some embodiments of the present disclosure, the encapsulant 35 does not cover the side surface of the interposer 32. In some embodiments of the present disclosure, the encapsulant 35 covers the side surfaces of the interposer 32. In some embodiments of the present disclosure, the encapsulant 35 surrounds the electrical connections 312 arranged between the interposer 32 and the substrate 31. In some embodiments of the present disclosure, the encapsulant 35 surrounds the electrical connections 314 arranged between the interposer 32 and the electronic component 381, 383. The encapsulant 35 may have a surface 353 (e.g., a lower surface) facing the substrate 31, and the electronic component 381, 383 may have a surface 3810, 3830 (e.g., a lower surface) which may be exposed from the surface 351 of the encapsulant 35 and substantially coplanar with the surface 351 of the encapsulant 35. In some embodiments of the present disclosure, the encapsulant 35 surrounds the electrical connections 322 arranged between the interposer 32 and the electronic component 385. Further, the encapsulant 35 may have a surface 351 (e.g., an upper surface) facing away from the substrate 31, and the electronic component 385 may have a surface 3850 (e.g., an upper surface) which may be exposed from the surface 351 of the encapsulant 35 and substantially coplanar with the surface 351 of the encapsulant 35.

Referring to FIG. 3, the motherboard 30 may include an aperture 300 extending through the motherboard 30, and the substrate 31 may include an aperture 310 extending through the substrate 31. The aperture 310 of the substrate 31 may substantially align with the aperture 300 of the motherboard 30. Further, the surfaces 3810, 3830 of the electronic components 381, 383, which are exposed form the surface 353 of the encapsulant 35, may substantially align with the aperture 310 of the substrate 31 and the aperture 300 of the motherboard 30. As shown in FIG. 3, the heat sink 33 is attached to the surfaces 3810, 3830 of the electronic components 381, 383 and a portion of the surface 353 of the encapsulant 35. In some embodiments of the present disclosure, the heat sink 33 extends through the aperture 310 of the substrate 31 and the aperture 300 of the motherboard 30 and extends to the outside of the semiconductor device package 3, so that the heat sink 33 is configured to transfer the heat, which may be generated by the electronic component(s) 381, 383 and other components in the semiconductor device package 3, from the interior of the semiconductor device package 3 to the outside of the semiconductor device package3. A thermal interface material 37 (TIM) is arranged between the surfaces 3810, 3830 of the electronic components 381, 383 and the heat sink 33 and between the surface 353 of the encapsulant 35 and the heat sink 33. That is, the electronic components 381, 383 and the encapsulant 35 are thermally connected to the heat sink 33 through the thermal interface material 37.

Moreover, the heat sink 34 may be disposed on or attached to the surface 351 of the encapsulant 35 and the surface 3850 of the electronic component 385 so that the heat sink 34 is configured to dissipate the heat generated from the electronic component 385. A thermal interface material 39 (TIM) is arranged between the heat sink 34 and the surface 351 of the encapsulant 35 and between the heat sink 34 and the surface 3850 of the electronic component 385. That is, the encapsulant 35 and the electronic component 385 are thermally connected and physically connected to the heat sink 34 through the thermal interface material 39.

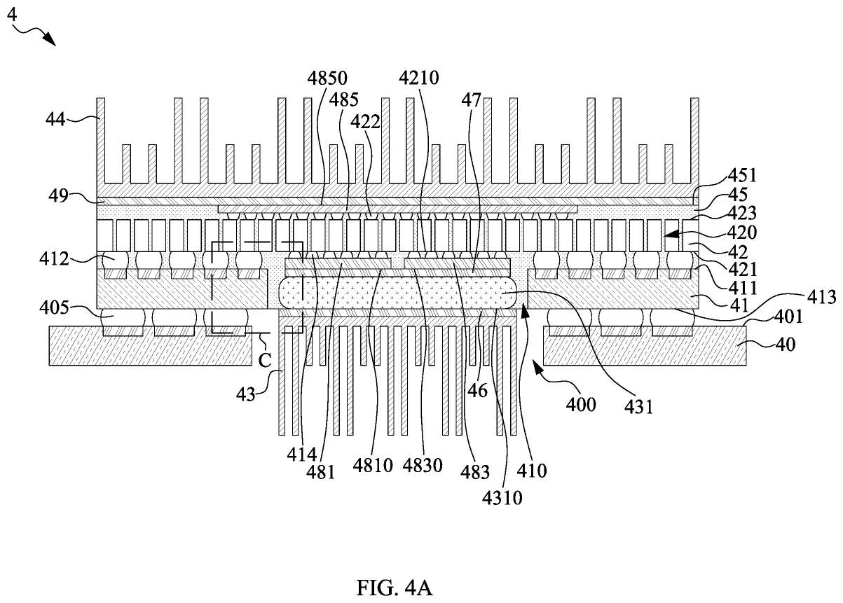

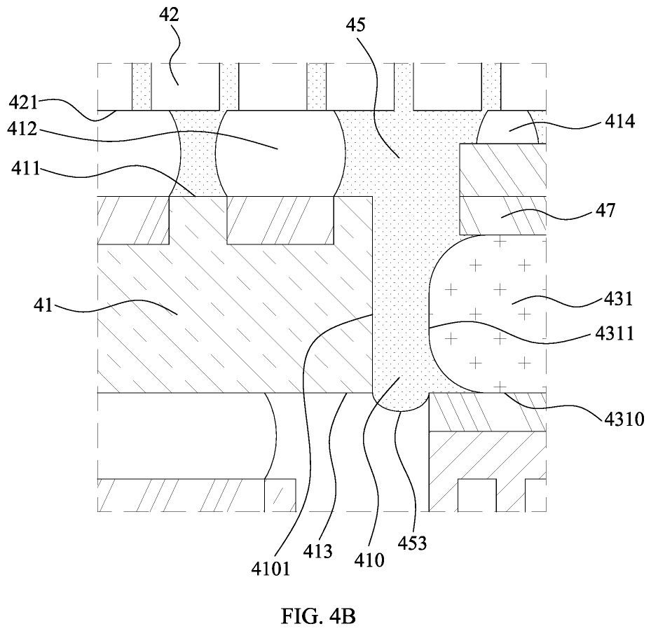

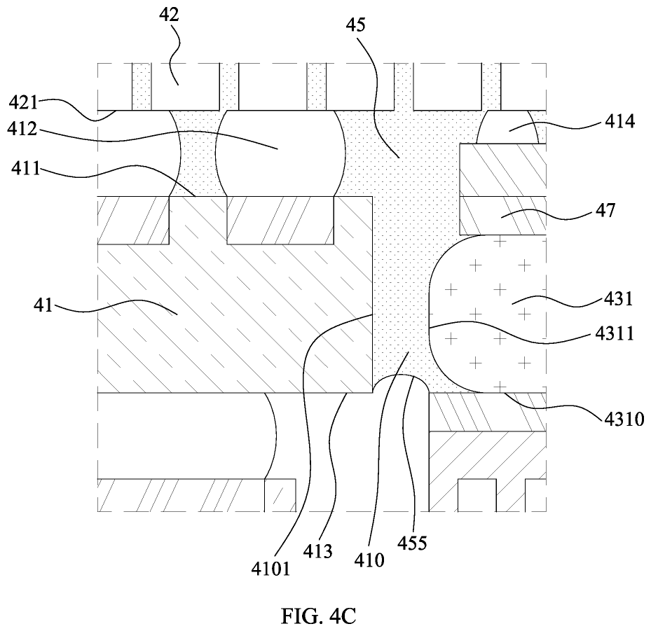

FIG. 4A is a cross-sectional view of a semiconductor device package 4 in accordance with some embodiments of the present disclosure. As shown in FIG. 4A, the semiconductor device package 4 includes a motherboard 40, a substrate 41, an interposer 42, heat sinks 43 and 44, a thermal spacer 431 and an encapsulant 45. In some embodiments of the present disclosure, the motherboard 40 includes a printed circuit board.

The motherboard 40 may have a surface 401 (e.g., an upper surface) and the substrate 41 may be disposed or mounted on the surface 401 of the motherboard 40. In some embodiments of the present disclosure, electrical connections 405 are disposed between the motherboard 40 and the substrate 41 so as to electrically connect the substrate 41 to the motherboard 40. The electrical connection 405 may include a solder ball or a solder bump such as a C4 bump. Further, the substrate 41 may have a surface 411 (e.g., an upper surface) facing away from the motherboard 40, and the interposer 42 may be disposed or mounted on the surface 411 of the substrate 41 so that the interposer 42 may be stacked on the substrate 41. In some embodiments of the present disclosure, the interposer 42 includes conductive vias 420 such as through silicon vias (TSVs). The interposer 42 may have a surface 421 (e.g., a lower surface) facing the surface 411 of the substrate 41. In some embodiments of the present disclosure, electrical connections 412 are disposed between the surface 421 of the interposer 42 and the surface 411 of the substrate 41 so as to electrically connect the interposer 42 to the substrate 41. The electrical connection 412 may include a C4 bump, a micro bump, a solder ball or a copper pillar. Further, electronic components 481 and 483 are disposed and mounted on the surface 421 of the interposer 42. The electronic components 481, 483 may be a die, an active device, a passive device, and/or other electronic devices. In some embodiments of the present disclosure, electrical connections 414 are disposed between the surface 421 of the interposer 42 and the electronic components 481, 483 so as to electrically connect the electronic components 481, 483 to the interposer 42. The electrical connection 414 may include a C4 bump, a micro bump, a solder ball or a copper pillar.

The substrate 41 may include an aperture 410 extending through the substrate 41, and the electronic component 481, 483 may have a surface 4810, 4830 (e.g., a lower surface) substantially aligning with the aperture 410 of the substrate 41. The thermal spacer 431 may be attached to the surfaces 4810, 4830 of the electronic components 481 and 483 and extend through the aperture 410 of the substrate 41. In some embodiments of the present disclosure, the substrate 41 includes a surface 413 (e.g., a lower surface) facing the motherboard 40 and the thermal spacer 431 includes a surface 4310 (e.g., a lower surface) facing away from the electronic component 481, 483, and the surface 413 of the substrate 41 and the surface 4310 of the thermal spacer 431 are substantially at a same elevation. Further, a thermal interface material 47 (TIM) is arranged between the surfaces 4810, 4830 of the electronic components 481, 483 and the thermal spacer 431. That is, the electronic components 481, 483 are thermally connected connected to the thermal spacer 431 through the thermal interface material 47.

The interposer 42 may have a surface 423 (e.g., an upper surface) facing away from the surface 411 of the substrate 41, and an electronic component 485 may be disposed or mounted on the surface 423 of the interposer 42. The electronic component 485 may be a die, an active device, a passive device, and/or other electronic devices. In some embodiments of the present disclosure, electrical connections 422 are disposed between the surface 423 of the interposer 42 and the electronic component 485 so as to electrically connect the electronic component 485 to the interposer 42. The electrical connection 422 may include a C4 bump, a micro bump, a solder ball or a copper pillar.

As shown in FIG. 4A, the encapsulant 45 (i.e., package body) may be disposed on the surface 411 of the substrate 41 and configured to cover, encapsulate or surround the surface 411 of substrate 41, the interposer 42, the electronic components 481, 483 and 485 and the thermal spacer 431. The encapsulant 45 may include molding compounds, such as a Novolac-based resin, an epoxy-based resin, a silicone-based resin, or other another suitable encapsulant; fillers such as silicon oxide fillers, may be included in the molding compound. In addition, the encapsulant 45 may include a molding underfill (MUF) or a capillary underfill (CUF). In some embodiments of the present disclosure, the encapsulant 45 covers the surfaces 421 and 423 of the interposer 42. In some embodiments of the present disclosure, the encapsulant 45 does not cover the side surface of the interposer 42. In some embodiments of the present disclosure, the encapsulant 45 covers the side surfaces of the interposer 42. In some embodiments of the present disclosure, the encapsulant 45 surrounds the electrical connections 412 arranged between the interposer 42 and the substrate 41. In some embodiments of the present disclosure, the encapsulant 45 surrounds the electrical connections 414 arranged between the interposer 42 and the electronic component 481, 483. Further, the surface 4310 of the thermal spacer 431 may be exposed form the encapsulant 45. In some embodiments of the present disclosure, the encapsulant 45 surrounds the electrical connections 422 arranged between the interposer 42 and the electronic component 485. Further, the encapsulant 45 may have a surface 451 (e.g., an upper surface) facing away from the substrate 41, and the electronic component 485 may have a surface 4850 (e.g., an upper surface) which may be exposed from the surface 451 of the encapsulant 45.

Referring to FIG. 4A, the motherboard 40 may include an aperture 400 extending through the motherboard 40. The aperture 400 of the motherboard 40 may substantially align with the aperture 410 of the substrate 41. Further, the surface 4310 of the thermal spacer 431, which is exposed form the encapsulant 45, may substantially align with the aperture 400 of the motherboard 40. As shown in FIG. 4A, the heat sink 43 is attached to the surface 4310 of the thermal spacer 431. In some embodiments of the present disclosure, the heat sink 43 extends through the aperture 400 of the motherboard 40 and extends to the outside of the semiconductor device package 4, so that the heat sink 43 is configured to transfer the heat, which may be generated by the electronic component(s) 481, 483 and other components in the semiconductor device package 4, from the interior of the semiconductor device package 4 to the outside of the semiconductor device package 4 through the thermal spacer 431. A thermal interface material 46 (TIM) is arranged between the surface 4310 of the thermal spacer 431 and the heat sink 43. That is, the thermal spacer 431 is thermally connected to the heat sink 43 through the thermal interface material 46.

FIG. 4B is an enlarged view of portion “C” illustrated in FIG. 4A and illustrates an embodiment of the semiconductor device package 4 as shown in FIG. 4A. As shown in FIG. 4B, the encapsulant 45 may cover the surfaces 421 of the interposer 42 and the surface 411 of the substrate 41 and surrounds the electrical connections 412, 414. Referring to FIGS. 4A and 4B, the thermal spacer 431 is located within the aperture 410 of the substrate 41. The thermal spacer 431 has a side surface 4311 facing and spaced from the inner surface 4101 of the aperture 410 of the substrate 41. In some embodiments of the present disclosure, the encapsulant 45 covers or contacts the inner surface 4101 of the aperture 410 of the substrate 41 and the side surface 4311 of the thermal spacer 431. In other words, there is a gap between the substrate 41 and the thermal spacer 431 and the encapsulant 45 may extend into the gap between the substrate 41 and the thermal spacer 431. The encapsulant 45 is configured to extend into the gap between the substrate 41 and the thermal spacer 431 and cover or contact the inner surface 4101 of the aperture 410 of the substrate 41 and the side surface 4311 of the thermal spacer 431, and thus functions as a mold lock. Further, the encapsulant 45 may cover or contact the thermal interface material 47. Moreover, the encapsulant 45 may have a surface 453 adjacent to the surface 413 of the substrate 41 and the surface 4310 of the thermal spacer 431 and located between the surface 413 of the substrate 41 and the surface 4310 of the thermal spacer 431. In some embodiments of the present disclosure, the surface 453 of the encapsulant 45 has a convex profile. Thus, the surface 453 of the encapsulant 45 may protrude from an elevation of the surface 413 of the substrate 41 and/or an elevation of the surface 4310 of the thermal spacer 431.

FIG. 4C is an enlarged view of portion “C” illustrated in FIG. 4A and illustrates an embodiment of the semiconductor device package 4 as shown in FIG. 4A. As shown in FIG. 4C, the encapsulant 45 may cover the surfaces 421 of the interposer 42 and the surface 411 of the substrate 41 and surrounds the electrical connections 412, 414. Referring to FIGS. 4A and 4C, the thermal spacer 431 is located within the aperture 410 of the substrate 41. The thermal spacer 431 has a side surface 4311 facing and spaced from the inner surface 4101 of the aperture 410 of the substrate 41. In some embodiments of the present disclosure, the encapsulant 45 covers or contacts the inner surface 4101 of the aperture 410 of the substrate 41 and the side surface 4311 of the thermal spacer 431. In other words, there is a gap between the substrate 41 and the thermal spacer 431 and the encapsulant 45 may extend into the gap between the substrate 41 and the thermal spacer 431. The encapsulant 45 is configured to extend into the gap between the substrate 41 and the thermal spacer 431 and cover or contact the inner surface 4101 of the aperture 410 of the substrate 41 and the side surface 4311 of the thermal spacer 431, and thus functions as a mold lock. Further, the encapsulant 45 may cover or contact the thermal interface material 47. Moreover, the encapsulant 45 may have a surface 455 adjacent to the surface 413 of the substrate 41 and the surface 4310 of the thermal spacer 431 and located between the surface 413 of the substrate 41 and the surface 4310 of the thermal spacer 431. In some embodiments of the present disclosure, the surface 455 of the encapsulant 45 has a concave profile. Thus, the surface 454 of the encapsulant 45 may be recessed with respect to an elevation of the surface 413 of the substrate 41 and/or an elevation of the surface 4310 of the thermal spacer 431.

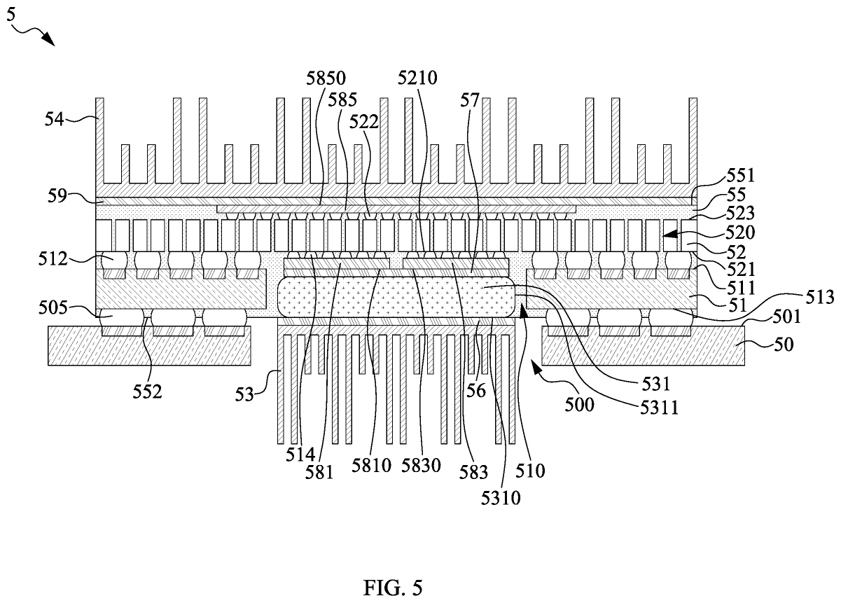

FIG. 5 is a cross-sectional view of a semiconductor device package 5 in accordance with some embodiments of the present disclosure. As shown in FIG. 5, the semiconductor device package 5 includes a motherboard 50, a substrate 51, an interposer 52, heat sinks 53 and 54, a thermal spacer 531 and an encapsulant 55. In some embodiments of the present disclosure, the motherboard 50 includes a printed circuit board.

The motherboard 50 may have a surface 501 (e.g., an upper surface) and the substrate 51 may be disposed or mounted on the surface 501 of the motherboard 50. In some embodiments of the present disclosure, the substrate 51 has a surface 513 (e.g., a lower surface) facing the surface 501 of the motherboard 50 and electrical connections 505 are disposed between the surface 501 of the motherboard 50 and the surface 513 of the substrate 51 so as to electrically connect the substrate 51 to the motherboard 50. The electrical connection 505 may include a solder ball or a solder bump such as a C4 bump. Further, the substrate 51 may have a surface 511 (e.g., an upper surface) facing away from the motherboard 500, and the interposer 52 may be disposed or mounted on the surface 511 of the substrate 51 so that the interposer 52 may be stacked on the substrate 51. In some embodiments of the present disclosure, the interposer 52 includes conductive vias 520 such as through silicon vias (TSVs). The interposer 52 may have a surface 521 (e.g., a lower surface) facing the surface 511 of the substrate 51. In some embodiments of the present disclosure, electrical connections 512 are disposed between the surface 521 of the interposer 52 and the surface 511 of the substrate 51 so as to electrically connect the interposer 52 to the substrate 51. The electrical connection 512 may include a C4 bump, a micro bump, a solder ball or a copper pillar. Further, electronic components 581 and 583 are disposed and mounted on the surface 521 of the interposer 52. The electronic components 581, 583 may be a die, an active device, a passive device, and/or other electronic devices. In some embodiments of the present disclosure, electrical connections 514 are disposed between the surface 521 of the interposer 52 and the electronic components 581, 583 so as to electrically connect the electronic components 581, 583 to the interposer 52. The electrical connection 514 may include a C4 bump, a micro bump, a solder ball or a copper pillar.

The substrate 51 may include an aperture 510 extending through the substrate 51, and the electronic component 581, 583 may have a surface 5810, 5830 (e.g., a lower surface) substantially aligning with the aperture 510 of the substrate 51. The thermal spacer 531 may be attached to the surfaces 5810, 5830 of the electronic components 581 and 583 and extend through the aperture 510 of the substrate 51. Further, a thermal interface material 57 (TIM) is arranged between the surfaces 5810, 5830 of the electronic components 581, 583 and the thermal spacer 531. That is, the electronic components 581, 583 are thermally connected to the thermal spacer 541 through the thermal interface material 57.

The interposer 52 may have a surface 523 (e.g., an upper surface) facing away from the surface 511 of the substrate 51, and an electronic component 585 may be disposed or mounted on the surface 523 of the interposer 52. The electronic component 585 may be a die, an active device, a passive device, and/or other electronic devices. In some embodiments of the present disclosure, electrical connections 522 are disposed between the surface 523 of the interposer 52 and the electronic component 585 so as to electrically connect the electronic component 585 to the interposer 52. The electrical connection 522 may include a C4 bump, a micro bump, a solder ball or a copper pillar.

As shown in FIG. 5, the encapsulant 55 (i.e., package body) is configured to cover, encapsulate or surround the substrate 51, the interposer 52, the electronic components 581, 583 and 585 and the thermal spacer 531. The encapsulant 55 may include molding compounds, such as a Novolac-based resin, an epoxy-based resin, a silicone-based resin, or other another suitable encapsulant; fillers such as silicon oxide fillers, may be included in the molding compound. In addition, the encapsulant 55 may include a molding underfill (MUF) or a capillary underfill (CUF). In some embodiments of the present disclosure, the encapsulant 55 covers the surfaces 521 and 523 of the interposer 52. In some embodiments of the present disclosure, the encapsulant 55 does not cover the side surface of the interposer 52. In some embodiments of the present disclosure, the encapsulant 55 covers the side surfaces of the interposer 52. In some embodiments of the present disclosure, the encapsulant 55 surrounds the electrical connections 512 arranged between the interposer 52 and the substrate 51. In some embodiments of the present disclosure, the encapsulant 55 surrounds the electrical connections 514 arranged between the interposer 52 and the electronic component 581, 583. In some embodiments of the present disclosure, the encapsulant 55 surrounds the electrical connections 522 arranged between the interposer 52 and the electronic component 585. Further, the encapsulant 55 may have a surface 551 (e.g., an upper surface) facing away from the surface 511 of the substrate 51, and the electronic component 585 may have a surface 5850 (e.g., an upper surface) which may be exposed from the surface 551 of the encapsulant 55. In some embodiments of the present disclosure, the encapsulant 55 covers the surfaces 511 and 513 of the substrate 511. In some embodiments of the present disclosure, the encapsulant 55 surrounds or contacts the electrical connections 505 arranged between the substrate 51 and the motherboard 50. The encapsulant 55 may include a surface 552 (e.g., a lower surface) facing the motherboard 50 and the thermal spacer 531 may include a surface 5310 (e.g., a lower surface) facing away from the electronic component 581, 583. The surface 5310 of the thermal spacer 531 may protrude from an elevation of the surface 513 of the substrate 51 and be exposed from the surface 552 of the encapsulant 55. In some embodiments of the present disclosure, the surface 552 of the encapsulant 55 and the surface 5310 of the thermal spacer 531 are substantially coplanar with each other.

As shown in FIG. 5, the thermal spacer 531 is located within the aperture 510 of the substrate 51. The thermal spacer 531 has a side surface 5311 facing and spaced from the inner surface 5101 of the aperture 510 of the substrate 51. In some embodiments of the present disclosure, the encapsulant 55 covers or contacts the inner surface 5101 of the aperture 510 of the substrate 51 and the side surface 5311 of the thermal spacer 531. In other words, there is a gap between the substrate 51 and the thermal spacer 531, and the encapsulant 55 may extend into the gap between the substrate 51 and the thermal spacer 531. The encapsulant 55 is configured to extend into the gap between the substrate 51 and the thermal spacer 531 and cover or contact the inner surface 5101 of the aperture 510 of the substrate 51 and the side surface 5311 of the thermal spacer 531, and thus functions as a mold lock. Further, the encapsulant 55 may cover or contact the thermal interface material 57.

Referring to FIG. 5, the motherboard 50 may include an aperture 500 extending through the motherboard 50. The aperture 500 of the motherboard 50 may substantially align with the aperture 510 of the substrate 51. Further, the surface 5310 of the thermal spacer 531, which is exposed form the encapsulant 55, may substantially align with the aperture 500 of the motherboard 50. As shown in FIG. 5, the heat sink 53 is attached to the surface 5310 of the thermal spacer 531. In some embodiments of the present disclosure, the heat sink 53 extends through the aperture 500 of the motherboard 50 and extends to the outside of the semiconductor device package 5, so that the heat sink 53 is configured to transfer the heat, which may be generated by the electronic component(s) 581, 583 and other components in the semiconductor device package 5, from the interior of the semiconductor device package 5 to the outside of the semiconductor device package 5 through the thermal spacer 531. A thermal interface material 56 (TIM) is arranged between the surface 5310 of the thermal spacer 531 and the heat sink 53. That is, the thermal spacer 531 is thermally connected to the heat sink 53 through the thermal interface material 56.

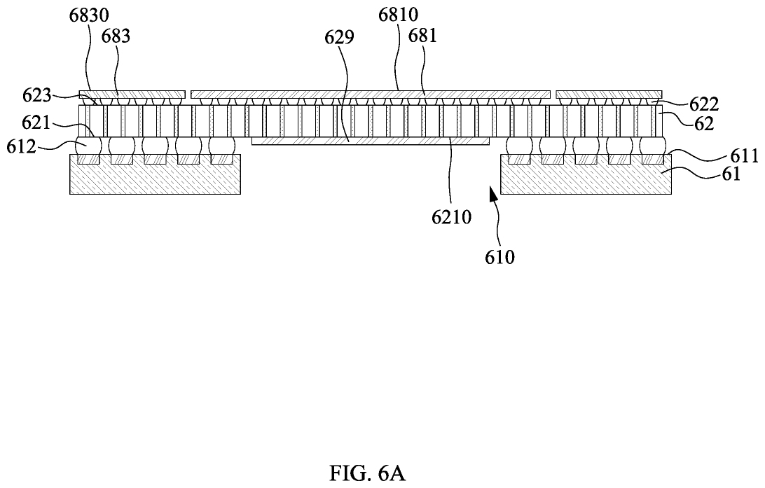

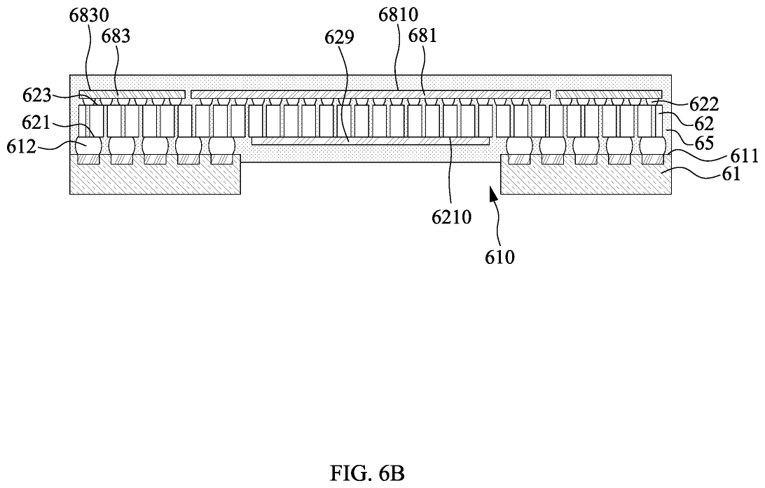

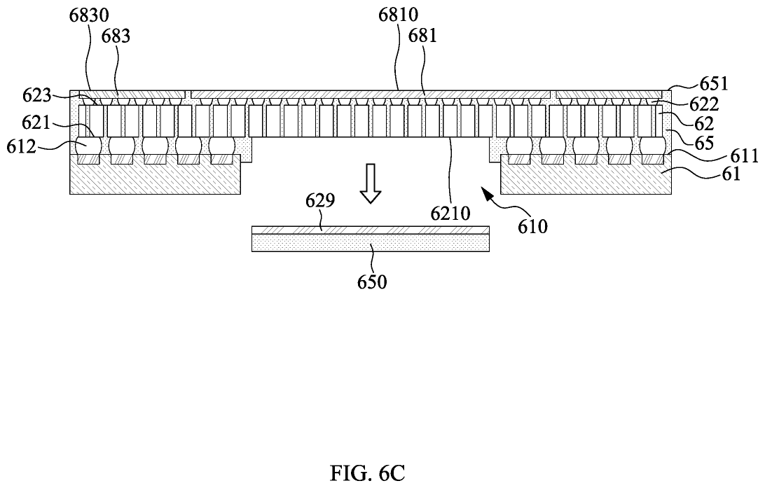

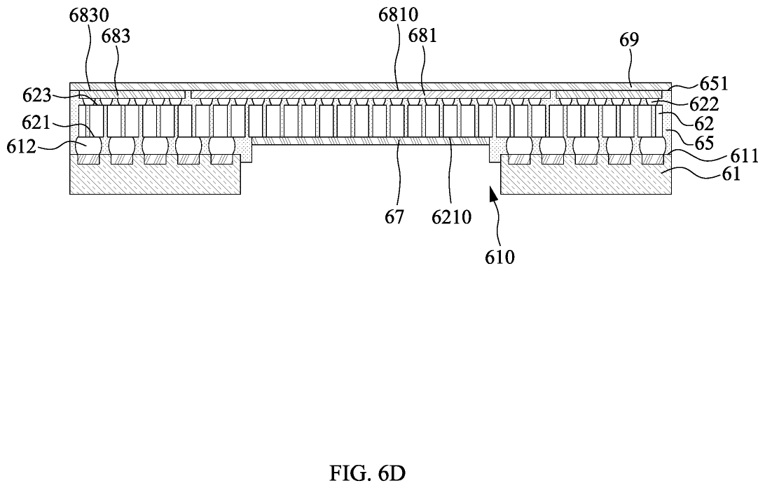

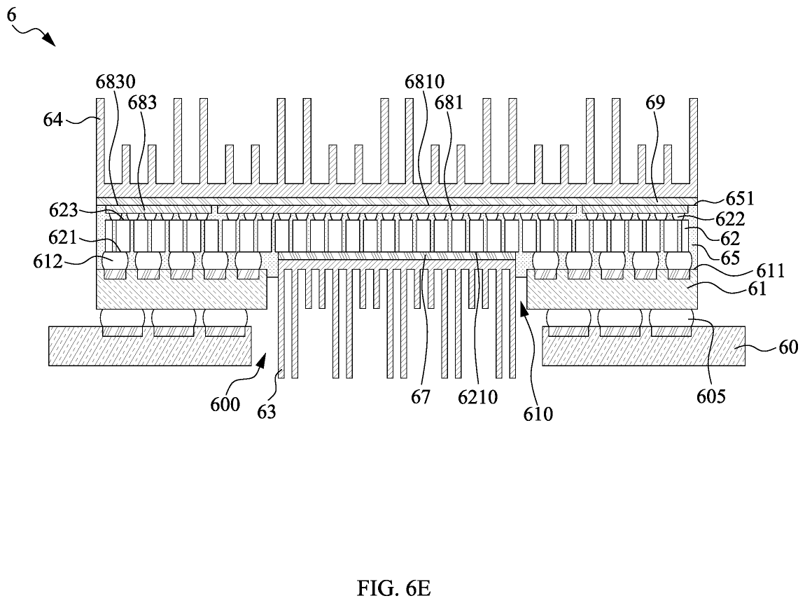

FIG. 6A, FIG. 6B, FIG. 6C, FIG. 6D and FIG. 6E show a method of manufacturing a semiconductor device package in accordance with an embodiment of the instant disclosure.

With reference to FIG. 6A, a substrate 61, an interposer 62 and electronic components 681, 683 are provided. The interposer 62 is disposed or mounted on the substrate 61. The substrate 61 includes a surface 611 facing the interposer 62, and the interposer 62 includes a surface 621 facing the substrate 61 and a surface 623 facing away from the substrate 61. A plurality of electrical connections 612 are disposed between the surface 621 of the interposer 62 and the surface 611 of the substrate 61. The electronic components 681, 683 are disposed or mounted on the surface 623 of the interposer 62. A plurality of electrical connections 622 are disposed between the surface 623 of the interposer 62 and the electronic components 681, 683. Moreover, the substrate 61 includes an aperture 610 extending through the substrate 61, and a removable/sacrificial layer 629 is disposed on the surface 621 of the interposer 62 and substantially aligns with the aperture 610 of the substrate 61. In some embodiments of the present disclosure, the removable/sacrificial layer 629 is a kind of the intermediate structure. The removable/sacrificial layer 629 is used to cover a portion 6210 of the surface 621 of the interposer 62, which would not be encapsulated by the encaspulant when the encapsulant is provided. In some embodiments of the present disclosure, the portion 6210 of the surface 621 of the interposer 62, which would not be encapsulated by the encaspulant when the encapsulant is provided, is covered by the a portion of the molding apparatus or a portion of the mold chase. In some embodiments of the present disclosure, the portion of the molding apparatus, which is used to cover the portion 6210 of the surface 621 of the interposer 62, is a kind of the intermediate structure.

With reference to FIG. 6B, an encapsulant 65 is provided. The encapsulant 65 covers or encapsulates the surface 611 of the substrate 61, the surfaces 621, 623 of the interposer 62 and the electronic components 681 and 683. Moreover, the encapsulant 65 surrounds the electrical connections 612 arranged between the interposer 62 and the substrate 61 and the electrical connections 622 between the electronic components 681, 683 and the interposer 62.

With reference to FIG. 6C, the removable/sacrificial layer 629 and a portion 650 of the encapsulant 65 are removed from the surface 621 of the interposer 62, so that the portion 6210 of the surface 621 of the interposer 62 is exposed from the encapulant 65. Further, the portion 6210 of the surface 621 of the interposer 62 substantially aligns with the aperture 610 of the substrate 61. Further, a portion of the encapsulant 65 is grinded so that the encapsulant 65 has an upper surface 651 substantially coplanar with the upper surfaces 6810, 6830 of the electronic components 681, 683 and/or the upper surfaces 6810, 6830 of the electronic components 681, 683 are exposed from the upper surface 651 of the encapsulant 65.

With reference to FIG. 6D, an thermal interface material (TIM) 67 is formed on the portion 6210 of the surface 621 of the interposer 62 and another thermal interface material (TIM) 69 is formed on the upper surfaces 6810, 6830 of the electronic components 681, 683 and the upper surface 651 of the encapsulant 65.

With reference to FIG. 6E, a motherboard 60 and heat sinks 63 and 64 are provided. The motherboard 60 includes an aperture 600 extending through the motherboard 60. The substrate 61 is disposed on the motherboard 60, and the aperture 610 of the substrate 61 substantially aligns with the aperture 600 of the motherboard 60. A plurality of electrical connections 605 are disposed between the substrate 61 and the motherboard 60. The heat sink 63 is disposed on the thermal interface material 67. The heat sink 63 extends through the aperture 610 of the substrate 61 and the aperture 600 of the motherboard 60. The heat sink 64 is disposed on the thermal interface material 69.

After the manufacturing process as shown in FIGS. 6A, 6B. 6C, 6D and 6E, the semiconductor device package 6 is formed (see FIG. 6E). In some embodiments of the present disclosure, the semiconductor device package 6 is the same as, or similar to, the semiconductor device package 1 shown in FIG. 1A.

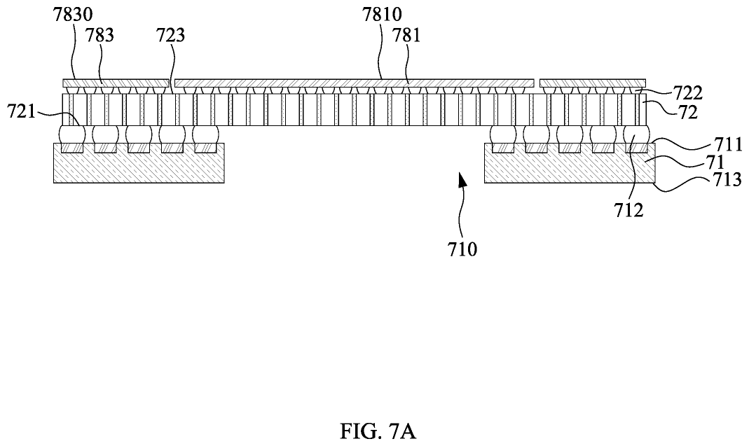

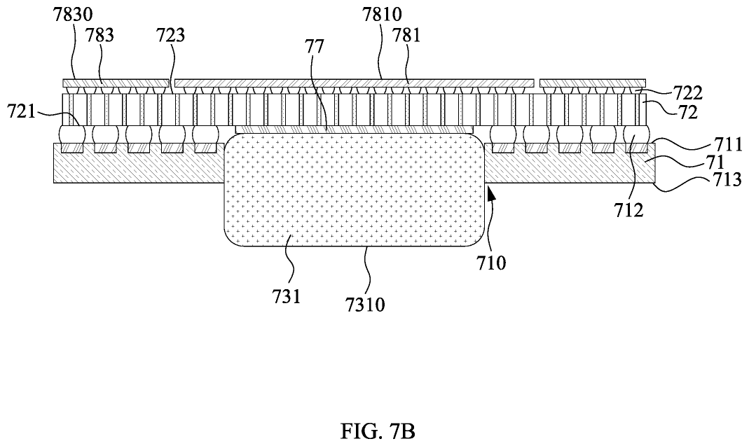

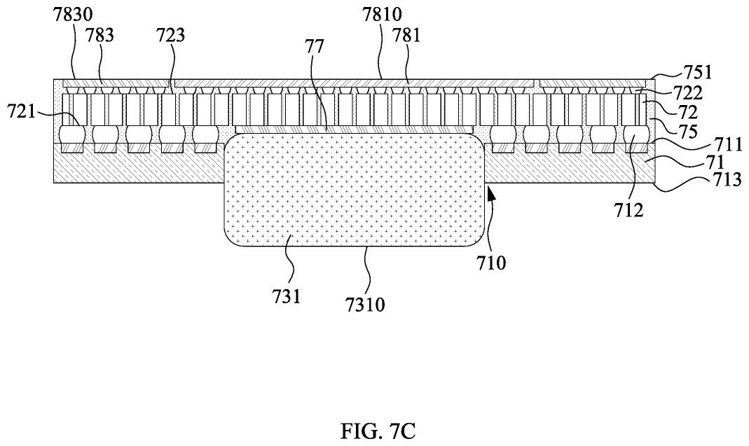

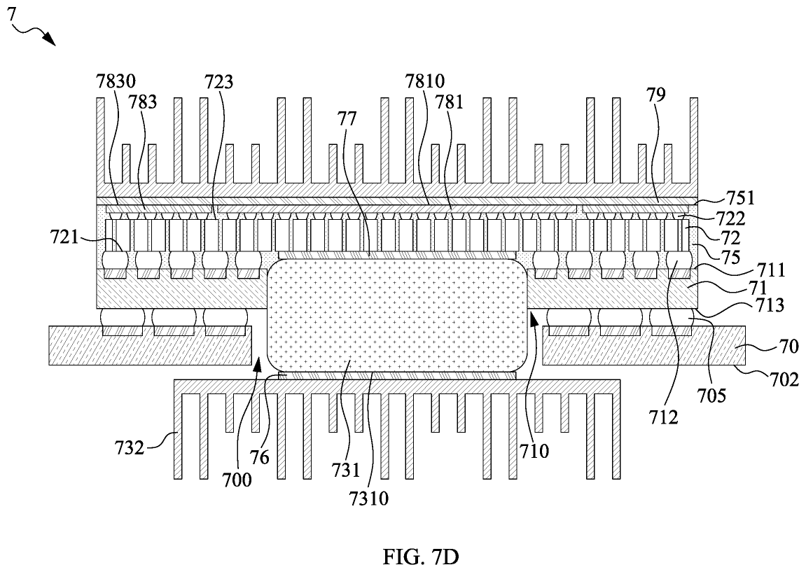

FIG. 7A, FIG. 7B, FIG. 7C and FIG. 7D show a method of manufacturing a semiconductor device package in accordance with an embodiment of the instant disclosure.

With reference to FIG. 7A, a substrate 71, an interposer 72 and electronic components 781, 783 are provided. The interposer 72 is disposed or mounted on the substrate 71. The substrate 71 includes a surface 711 facing the interposer 72, and the interposer includes a surface 721 facing the substrate 71 and a surface 723 facing away from the substrate 71. A plurality of electrical connections 712 are disposed between the surface 721 of the interposer 72 and the surface 711 of the substrate 71. The electronic components 781, 783 are disposed or mounted on the surface 723 of the interposer 72. A plurality of electrical connections 722 are disposed between the surface 723 of the interposer 72 and the electronic components 781, 783. Moreover, the substrate 71 includes an aperture 710 extending through the substrate 71.

With reference to FIG. 7B, a thermal interface material 77 is formed on the surface 721 of the interposer 72. The thermal interface material 77 substantially aligns with the aperture 710 of the substrate 71. Further, a thermal spacer 731 is disposed on the thermal interface material 77. In some embodiments of the present disclosure, the thermal spacer 731 is a kind of the intermediate structure. The thermal spacer 731 extends through the aperture 710 of the substrate 71 and has a lower surface 7310 protruding from an elevation of a lower surface 713 of the substrate 71.

With reference to FIG. 7C, an encapsulant 75 is provided. The encapsulant 75 covers or encapsulates the surface 711 of the substrate 71, the surfaces 721, 723 of the interposer 72, the electronic components 781 and 783 and the thermal spacer 731. Moreover, the encapsulant 75 surrounds the electrical connections 712 arranged between the interposer 72 and the substrate 71 and the electrical connections 722 between the electronic components 781, 783 and the interposer 72. Further, a grinding operation may be performed on the encapsulant such that the encapsulant 75 has an upper surface 751 which may be substantially coplanar with the upper surfaces 7810, 7830 of the electronic components 781, 783. In some embodiments of the present disclosure, the upper surfaces 7810, 7830 of the electronic components 781, 783 are exposed from the upper surface 751 of the encapsulant 75.

With reference to FIG. 7D, a motherboard 70, thermal interface materials (TIM) 76, 79 and heat sinks 732 and 74 are provided. The motherboard 70 includes an aperture 700 extending through the motherboard 70. The substrate 71 is disposed on the motherboard 70 and the aperture 710 of the substrate 71 substantially aligns with the aperture 700 of the motherboard 70, and thus the thermal spacer 731 extends through the aperture 700 of the motherboard 70. Further, the lower surface 7310 of the thermal spacer 731 protrudes from an elevation of a lower surface 702 of the motherboard 70. A plurality of electrical connections 705 are disposed between the substrate 71 and the motherboard 70. The thermal interface material 76 is formed on the lower surface 7310 of the thermal spacer 731, and the heat sink 732 is disposed on the thermal interface material 78. Since the lower surface 7310 of the thermal spacer 731 protrudes from an elevation of the lower surface 702 of the motherboard 70, the heat sink 732 is substantially located outside the motherboard 70. Moreover, a cross-sectional width of the heat sink 732 is greater than a cross-sectional width of the aperture 700 of the motherboard 70 and/or greater than a cross-sectional width of the aperture 710 of the substrate 71. The thermal interface material 79 is formed on the upper surface 751 of the encapsulant 75 and the upper surfaces 7810, 7830 of the electronic components 781, 783, and the heat sink 74 is disposed on the thermal interface material 79.

After the manufacturing process as shown in FIG. 7A, 7B. 7C, and 7D, the semiconductor device package 7 is formed (see FIG. 7D). In some embodiments of the present disclosure, the semiconductor device package 7 is the same as, or similar to, the semiconductor device package 2 shown in FIG. 2A.

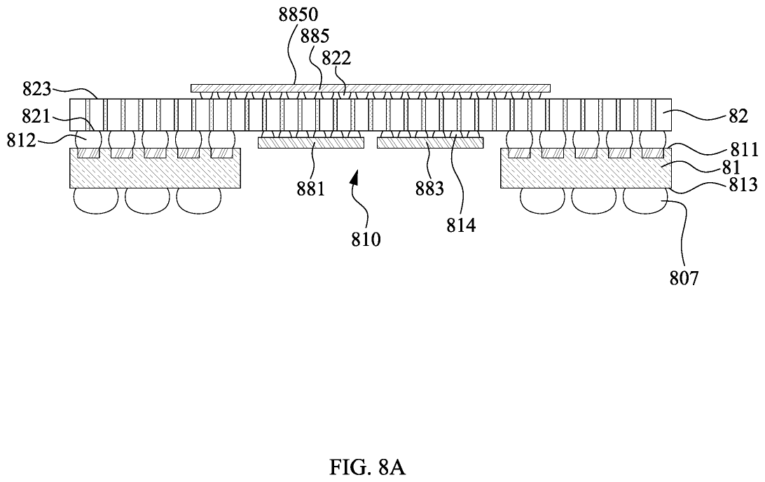

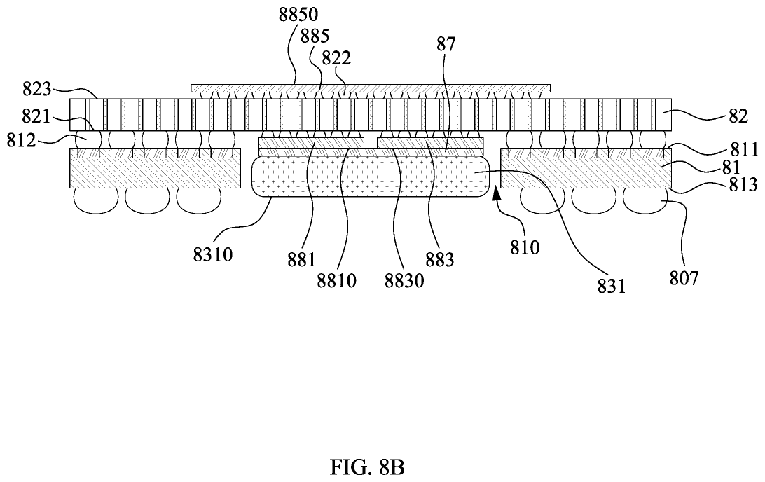

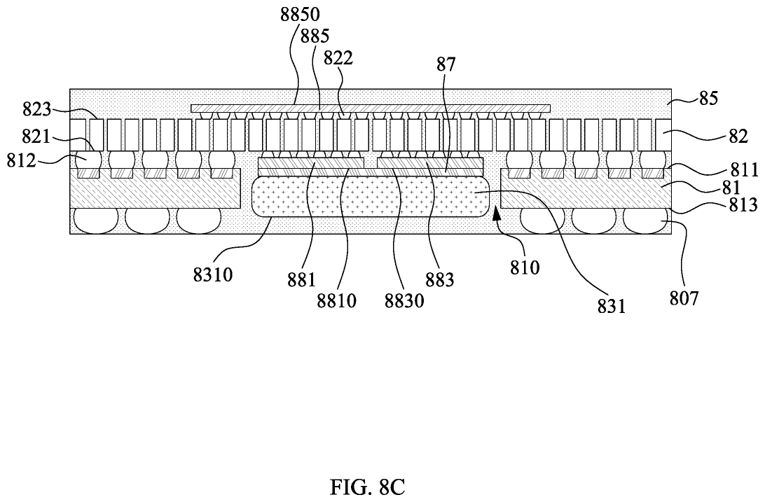

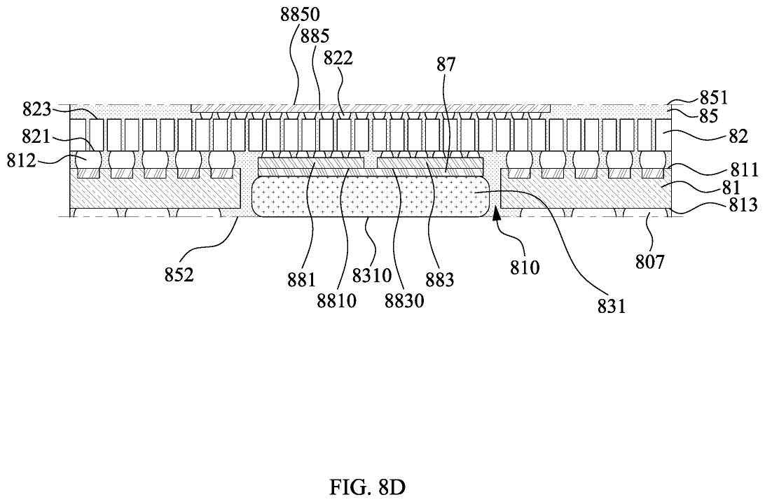

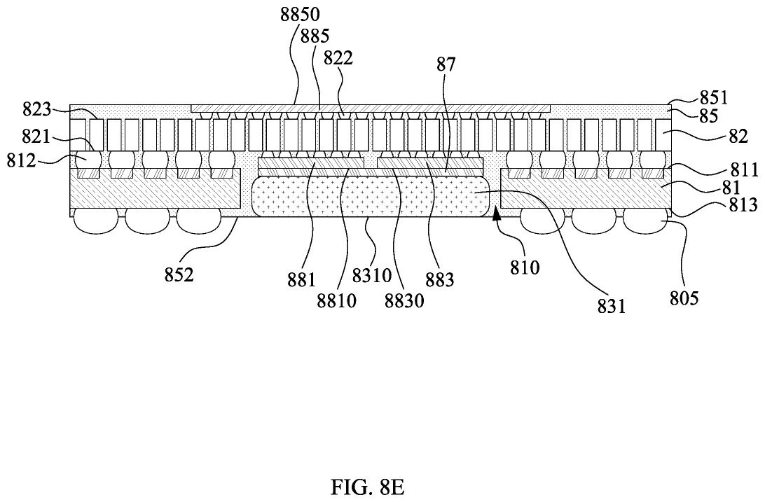

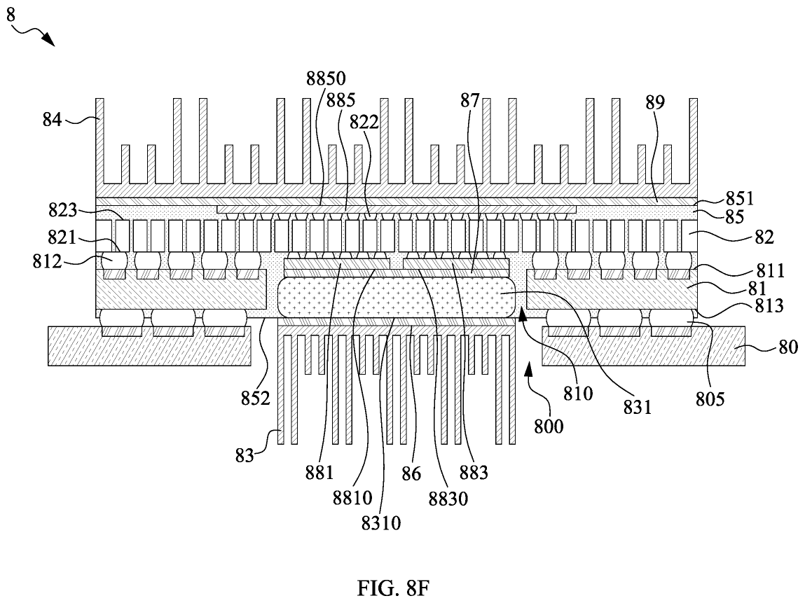

FIG. 8A, FIG. 8B, FIG. 8C, FIG. 8D, FIG. 8E and FIG. 8F show a method of manufacturing a semiconductor device package in accordance with an embodiment of the instant disclosure.

With reference to FIG. 8A, a substrate 81, an interposer 82, electronic components 881, 883, 885 and a plurality of conductive bumps 807 are provided. The interposer 82 is disposed or mounted on the substrate 81. The substrate 81 includes a surface 811 facing the interposer 82 and a surface 813 facing away the interposer 82, and the interposer 82 includes a surface 821 facing the substrate 811 and a surface 823 facing away from the substrate 81. A plurality of electrical connections 812 are disposed between the surface 821 of the interposer 82 and the surface 811 of the substrate 81. The electronic components 881, 883 are disposed or mounted on the surface 821 of the interposer 82. A plurality of electrical connections 814 are disposed between the surface 821 of the interposer 82 and the electronic components 881, 883. Moreover, the substrate 81 includes an aperture 810 extending through the substrate 81, and the electronic components 881, 883 substantially aligns with the aperture 810 of the substrate 81. The electronic component 885 is disposed or mounted on the surface 823 of the interposer 82. A plurality of electrical connections 822 are disposed between the surface 823 of the interposer 82 and the electronic component 885. Moreover, the conductive bumps 807 are disposed on the surface 813 of the substrate 81.

With reference to FIG. 8B, the thermal interface material (TIM) 87 and the thermal spacer 831 are provided. The electronic components 881 and 883 include lower surfaces 8810 and 8830 facing away from the interposer 82, and the thermal interface material 87 is formed on the lower surfaces 8810, 8830 of the electronic components 881, 883. Further, the thermal spacer 831 is disposed on the thermal interface material 87. In some embodiments of the present disclosure, the thermal spacer 831 is a kind of the intermediate structure. The thermal spacer 831 extends through the aperture 810 of the substrate 81 and has a lower surface 8310 protruding from an elevation of the surface 813 of the substrate 81.

With reference to FIG. 8C, an encapsulant 85 is provided. The encapsulant 85 covers or encapsulates the surfaces 811, 813 of the substrate 81, the surfaces 821, 823 of the interposer 82, the electronic components 881, 883 and 885 and the thermal spacer 831. Moreover, the encapsulant 85 surrounds the electrical connections 812 arranged between the interposer 82 and the substrate 81, the electronic connections 814 between the electronic components 881, 883 and the interposer 82 and the electrical connections 822 between the electronic component 885 and the interposer 82.

With reference to FIG. 8D, portions of the encapsulant 85 are removed so that the encapsulant 85 includes an upper surface 851 and a lower surface 852. In some embodiments of the present disclosure, the portions of the encapsulant 85 are removed by the grinding operation. After the portions of the encapsulant 85 are removed, an upper surface 8850 of the electronic component 885 is exposed from the upper surface 851 of the encapsualnt 85 and/or substantially coplanar with the upper surface 851 of the encaspsulant 85 and the lower surface 8310 of the thermal spacer 831 is exposed from the lower surface 852 of the encapsulant 85 and/or substantially coplanar with the lower surface 852 of the encapsulant 85. Moreover, portions of the conductive bumps 807 are accordingly removed, so that the truncated conductive bumps 807 are formed with their lower ends being substantially coplanar with the lower surface 852 of the encapsulant 85.

With reference to FIG. 8E, the truncated conductive bumps 807 are reflowed, and then the electrical connections 805 are formed with their lower ends protruding from the lower surface 852 of the encapsulant 85.

With reference to FIG. 8F, a motherboard 80, thermal interface materials (TIM) 86, 89 and heat sinks 83 and 84 are provided. The motherboard 80 includes an aperture 800 extending through the motherboard 80. The substrate 81 is disposed on the motherboard 80 and the aperture 810 of the substrate 81 substantially aligns with the aperture 800 of the motherboard 80 and the electrical connections 805 are arranged between the substrate 81 and the motherboard 80. The thermal interface material 86 is formed on the lower surface 8310 of the thermal spacer 831, and the heat sink 83 is disposed on the thermal interface material 86. The heat sink 83 extends through the aperture 800 of the motherboard 80. The thermal interface material 89 is formed on the upper surface 851 of the encapsulant 85 and the upper surfaces 8810, 8830 of the electronic components 881, 883, and the heat sink 84 is disposed on the thermal interface material 89.

After the manufacturing process as shown in FIGS. 8A, 8B. 8C, 8D, 8E and 8F, the semiconductor device package 8 is formed (see FIG. 8F). In some embodiments of the present disclosure, the semiconductor device package 8 is the same as, or similar to, the semiconductor device package 5 shown in FIG. 5.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor device package, comprising:
a first substrate having an aperture;
a second substrate disposed on the first substrate and having a first surface facing the first substrate;
a first electronic component disposed on the second substrate;
an encapsulant disposed on the first substrate and covering the second substrate; and
a first heat dissipation structure arranged in the aperture and disposed on the first surface of the second substrate.

2. The semiconductor device package of claim 1, further comprising a first thermal interface material between the first heat dissipation structure and the first surface of the second substrate.

3. The semiconductor device package of claim 1, wherein the first electronic component is disposed on a second surface of the second substrate, which faces away from the first substrate, and surrounded by the encapsulant, and wherein a second heat dissipation structure is attached to the first electronic component.

4. The semiconductor device package of claim 1, wherein a portion of the first surface of the second substrate substantially aligns the aperture and is exposed from the encapsulant, and wherein the first heat dissipation structure is attached to the portion of the first surface of the second substrate.

5. The semiconductor device package of claim 1, wherein the first heat dissipation structure comprises a side surface facing an inner surface of the aperture of the first substrate, and wherein the encapsulant covers the inner surface of the aperture of the first substrate and the side surface of the first heat dissipation structure.

6. The semiconductor device package of claim 1, wherein the first heat dissipation structure comprises a thermal spacer and a heat sink element, and wherein the thermal spacer is disposed on the first surface of the second substrate and the heat sink element is attached to the thermal spacer by a second thermal interface material.

7. The semiconductor device package of claim 6, wherein a cross-sectional width of the heat sink element is greater than a cross-sectional width of the aperture of the first substrate.

8. The semiconductor device package of claim 6, wherein the encapsulate comprises a surface between the first substrate and the thermal spacer and having a convex profile or a concave profile.

9. The semiconductor device package of claim 1, wherein the first substrate comprises a surface facing away from the second substrate, and wherein the encapsulant covers the surface of the first substrate.

10. A semiconductor device package, comprising:
a carrier;
a package structure staked on the carrier, wherein the packages structure comprises a set of stacked components and an encapsulant surrounding the set of the stacked components;
a first heat dissipation structure extending through the carrier and into the package structure, wherein the first heat dissipation structure is configured to abut the set of the stacked components; and
a first thermal interface material between the first heat dissipation structure and the set of the stacked components.

11. The semiconductor device package of claim 10, wherein the set of stacked components comprises an interposer and a portion of the interposer is exposed from the encapsulant, and wherein the first heat dissipation structure is attached to the portion of the interposer through the first thermal interface material.

12. The semiconductor device package of claim 10, wherein the set of stacked components comprises an interposer with a first surface facing the carrier and a first electronic component mounted on the first surface of the interposer and exposed from the encapsulant, and wherein the first heat dissipation structure is attached to the first electronic component through the first thermal interface material.

13. The semiconductor device package of claim 10, wherein the first heat dissipation structure comprises a thermal spacer and a heat sink element, and wherein the thermal spacer is attached to the set of the stacked components through the first thermal interface material and the heat sink element is attached to the thermal spacer by a second thermal interface material.

14. The semiconductor device package of claim 13, wherein the ecnapsulant fills a space between the thermal spacer and the package structure.

15. The semiconductor device package of claim 13, wherein the whole heat sink element is positioned on a first surface of the carrier, which faces away from the package structure, and wherein a cross-sectional width of the heat sink is greater than a cross-sectional width of the thermal spacer.

16. A method of manufacturing a semiconductor device package, comprising:
providing a semiconductor structure with a set of stacked components;
providing an intermediate structure on a portion of the semiconductor structure;
forming an encapsulant on the semiconductor structure to encapsulate the set of stacked components and the intermediate structure so that an aperture is formed in the encapsulant;
providing a heat dissipation structure in the aperture or on the intermediate structure.

17. The method of claim 16, further comprising: removing the intermediate structure from the semiconductor device package to form the aperture in the encapsulant, wherein the heat dissipation structure is configured to extend through the aperture.

18. The method of claim 16, wherein the heat dissipation structure is configured to abut the set of stacked components of the semiconductor structure.

19. The method of claim 16, further comprising: providing a thermal interface material on the portion of the semiconductor structure before providing the heat dissipation in the aperture.

20. The method of claim 17, wherein the intermediate structure comprises a sacrificial layer or a portion of a molding apparatus.
